(19) United States
(12) Patent Application Publication
(10) Pub. No.: US 2012/0213947 A1
(43) Pub. Date: Aug. 23, 2012

(54) DEPOSITING THIN LAYER OF MATERIAL ON PERMEABLE SUBSTRATE

(75) Inventor: Sang In LEE, Sunnyvale, CA (US)

(73) Assignee: SYNOS TECHNOLOGY, INC., Sunnyvale, CA (US)

(21) Appl. No.: 13/372,290

(22) Filed: Feb. 13, 2012

Related U.S. Application Data
(60) Provisional application No. 61/444,658, filed on Feb. 18, 2011.

(51) Int. Cl. C23C 16/44; H05H 1/24; C23C 16/04

(52) U.S. Cl. 427/569; 118/719; 427/209

(57) ABSTRACT

Embodiments relate to depositing a layer of material on a permeable substrate by passing the permeable substrate between a set of reactors. The reactors may inject source precursor, reactant precursor, purge gas or a combination thereof onto the permeable substrate as the permeable substrate passes between the reactors. Part of the gas injected by a reactor penetrates the permeable substrate and is discharged by the other reactor. The remaining gas injected by the reactor moves in parallel to the surface of the permeable substrate and is discharged via an exhaust portion formed on the same reactor.

### CROSS-REFERENCE TO RELATED APPLICATION

This application claims priority under 35 U.S.C. §119(e) to co-pending U.S. Provisional Patent Application No. 61/444,658, filed on Feb. 18, 2011, which is incorporated by reference herein in its entirety.

### BACKGROUND

1. Field of Art

The disclosure relates to depositing one or more layers of materials on a permeable substrate by injecting precursor onto the permeable substrate.

2. Description of the Related Art

Permeable substrates such as membrane and fabric have various applications. The permeable substrates may be deposited with certain materials to enhance or modify various characteristics of the substrates. For example, some applications require high melting point and high strength in the permeable substrates. To obtain the desired characteristics, the permeable substrates may be deposited with materials that have a melting point and strength higher than the permeable substrates.

Applications of permeable substrates include their use as separators in rechargeable batteries (e.g., Lithium-ion battery). Such separators are often formed by depositing powder onto a porous polyethylene membrane. The polyethylene membrane generally has a thickness about 25 μm or less, pore size less than 1 μm and porosity of about 40% or less. By depositing powder (e.g., Al₂O₃) onto the polyethylene membrane, the polyethylene membrane may retain its shape even in a high temperature. In order to prevent premature melting of the polyethylene membrane due to insufficient coating, the power is coated to a significant thickness on the polyethylene membrane. Due to the thickness of the membrane, the packing density of the rechargeable is decreased (i.e., the size of the battery is increased).

In other applications such as facial tissue or diaper, water resistant is required in addition to high strength and melting point. Such characteristics can be achieved by depositing oxide such as Al₂O₃ or TiO₂, nitride such as SiN and carbon material such as graphene onto paper to a thickness in the range of several tens of angstroms or several hundreds of angstroms.

The cost or time associated with the depositing the material onto the substrate may be significant, increasing the overall cost of time associated with fabricating the permeable substrate. Moreover, the quality of the deposited materials may be lower than desired, decreasing the quality of products or increasing the amount of permeable substrates needed in the products.

### SUMMARY

Embodiments relate to depositing a layer of material on a permeable substrate by using a depositing device including two reactors that face each other. One reactor faces one surface of the permeable substrate and injects precursor onto the surface of the permeable substrate. The other reactor faces another surface of the permeable substrate and injects the same or different precursor onto the other surface of the permeable substrate. At least part of the precursor injected by the first reactor or the second reactor penetrates the permeable substrate and is discharged by the second reactor or the first reactor.

In one embodiment, the deposition device further includes a mechanism for causing relative movement between the permeable substrate and the first and second reactors.

In one embodiment, the reactor comprises a first injector configured to inject the precursor onto the surface, and the other reactor includes a second injector configured to inject another type of precursor onto the other surface of the permeable substrate. Each of the first and second injectors includes a body formed with a reaction chamber facing the permeable substrate.

In one embodiment, the body is further formed with an exhaust portion configured to discharge excess portion of the precursor, and a constriction zone connecting the exhaust portion and the reaction chamber. The constriction zone may have a height less than ⅔ of the reaction chamber.

In one embodiment, the reactor further includes a third injector configured to inject precursor onto the surface of the permeable substrate. The other reactor further includes a fourth injector configured to inject the same or different precursor onto the other surface of the permeable substrate.

In one embodiment, the device performs atomic layer deposition (ALD) or molecular layer deposition (MLD) by injecting the precursors.

Embodiments also relate to a method of depositing material on a permeable substrate. A first precursor is injected onto a surface of the permeable substrate by a first reactor facing the surface of the permeable substrate. A second precursor is injected onto another surface of the permeable substrate by a second reactor facing the other surface of the permeable substrate. At least part of the first precursor that penetrated the permeable substrate is discharged by the second reactor.

### BRIEF DESCRIPTION OF DRAWINGS

FIG. 1 is a perspective view of a deposition device, according to one embodiment.

FIG. 2 is a cross sectional view of the deposition device of FIG. 1 taken along line A-B, according to one embodiment.

FIG. 3 is a perspective view of the deposition device of FIG. 1 cut in half, according to one embodiment.

FIG. 4 is a diagram illustrating flow of precursor material below a source injector, according to one embodiment.

FIG. 5A is a cross sectional view of a deposition device including radical reactors, according to one embodiment.

FIG. 5B is a cross sectional view of a deposition device including a radical reactor, according to another embodiment.

FIG. 6 is a flowchart illustrating a process of performing deposition, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to depositing a layer of material on a permeable substrate by passing the permeable substrate between a set of reactors. The reactors may inject source precursor, reactant precursor, purge gas or a combination thereof onto the permeable substrate as the permeable substrate passes between the reactors. Part of the gas injected by a reactor penetrates the permeable substrate and is discharged by the other reactor. The remaining gas injected by the reactor moves in parallel to the surface of the permeable substrate and is discharged via an exhaust portion formed on the same reactor. While penetrating the substrate or moving in parallel to the surface, the source precursor or the reactant precursor becomes absorbed on the substrate or react with precursor already present on the substrate.

Permeable substrate described herein refers to a substrate having a planar structure where at least part of gases or liquids injected on one side of the substrate can penetrate to the opposite side of the substrate. The permeable substrate includes, among others, textile, membrane and fabric, and web. The permeable structure may be made of various materials including, among other materials, paper, polyethylene, porous metal, wool, cotton and flax.

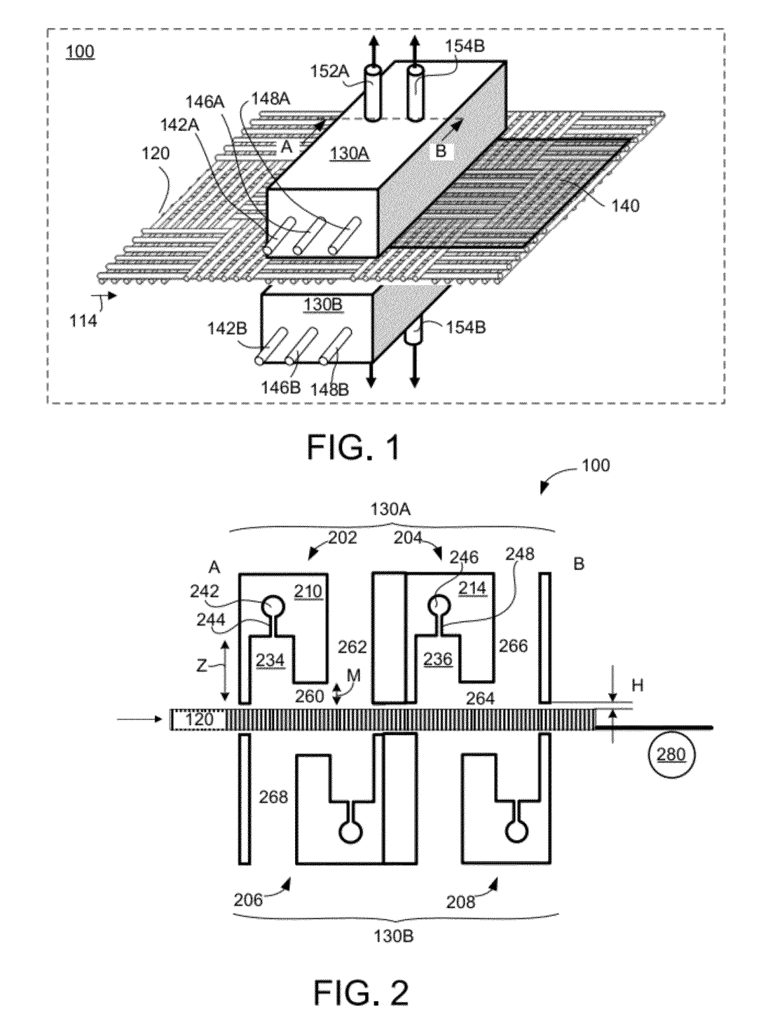

FIG. 1 is a perspective view of a deposition device 100, according to one embodiment. The deposition device 100 may include, among other components, an upper reactor 130A and a lower reactor 130B. A permeable substrate 120 moves from the left to right (as indicated by arrow 114) and passes between the upper and lower reactors 130A, 130B, the permeable substrate 120 is deposited with a layer 140 of material. The entire deposition device 100 may be enclosed in a vacuum or in a pressurized vessel. Although the deposition device 100 is illustrated as depositing material on the substrate 120 as the substrate moves horizontally, the deposition device 100 may be oriented so that the layer 140 is deposited as the substrate 120 moves vertically or in a different direction.

The upper reactor 130A is connected to pipes 142A, 146A, 148A supplying precursor, purge gas and a combination thereof into the upper reactor 130A. Exhaust pipes 152A and 154A are also connected to the upper reactor 130A to discharge excess precursor and purge gas from the interior of the upper reactor 130A. The upper reactor 130A has its lower surface facing the substrate 120.

The lower reactor 130B is also connected to pipes 142B, 146B, 148A to receive precursor, purge gas and a combination thereof. Exhaust pipes (e.g., pipe 154B) are also connected to the lower reactor 130B to discharge excess precursor and purge gas from the interior of the lower reactor 130B. The lower reactor 130B has it upper surface facing the substrate 120.

The deposition device 100 may perform atomic layer deposition (ALD), molecular layer deposition (MLD) or chemical vapor deposition (CVD) on the substrate 120 as the substrates moves from the left to the right between the lower surface of the upper reactor 130A and the upper surface of the lower reactor 130B. ALD is performed by injecting source precursor on the substrate followed by reactant precursor on the substrate. The MLD is substantially the same as ALD except that a hybrid polymer is formed on the substrate. In CVD, the source precursor and the reactant precursor is mixed before injection onto the substrate 120. The deposition device 100 may perform one or more of ALD, MLD or CVD based on gases supplied to the reactors 130A, 130B and other operating conditions.

FIG. 2 is a cross sectional view of the deposition device 100 taken along line A-B of FIG. 1, according to one embodiment. The upper reactor 130A may include, among other components, a source injector 202 and a reactant injector 204. The source injector 202 is connected to the pipe 142A to receive the source precursor (in combination with carrier gas such as Argon) and the reactant injector 204 is connected to the pipe 148A to receive reactant precursor (in combination with carrier gas such as Argon). The carrier gas may be injected via a separate pipe (e.g., pipe 146A) or via the pipes that supply the source or reactant precursor.

The body 210 of the source injector 202 is formed with a channel 242, perforations (e.g., holes or slits) 244, a reaction chamber 234, a constriction zone 260 and an exhaust portion 262. The source precursor flows into the reaction chamber 234 via the channel 242 and the perforations 244, and reacts with the permeable substrate 120. Part of the source precursor penetrates the substrate 120 and is discharged via an exhaust portion 268 formed on the lower reactor 130B. The remaining source precursor flows through the constriction zone 260 in parallel to the surface of the substrate 120 and is discharged into the exhaust portion 262. The exhaust portion is connected to the pipe 152A and discharges the excess source precursor out of the injector 202.

When the source precursor flows through the constriction zone 260, excess source precursor is removed from the surface of the substrate 120 due to the higher speed of the source precursor in the construction zone 260. In one embodiment, the height M of the constriction zone 260 is less than ⅔ the height Z of the reaction chamber 234. Such height M is desirable to remove the source precursor from the surface of the substrate 120.

The reactant injector 204 has a similar structure as the source injector 202. The reactant injector 204 receives the reactant precursor and injects the reactant precursor onto the substrate 120. The source injector 204 has a body 214 formed with a channel 246, perforations 248, a reaction chamber 236, a constriction zone 264 and an exhaust portion 266. The functions and the structures of these portions of the reactant injector 204 are substantially the same as counterpart portions of the source injector 202. The exhaust portion 266 is connected to the pipe 154B.

The lower reactor 130B has a similar structure as the upper reactor 130A but has an upper surface facing a direction opposite to the upper reactor 130A. The lower reactor 130B may include a source injector 206 and a reactor injector 208. The source injector 206 receives the source precursor via the pipe 142B and injects the source precursor onto the rear surface of the substrate 120. Part of the source precursor penetrates the substrate 120 and is discharged via the exhaust portion 262. The remaining source precursor flows into the exhaust portion 268 in parallel to the surface of the substrate 120 and is discharged from the source injector.

The structure of the reactor injector 208 is substantially the same as the reactor injector 204, and therefore, detailed description thereof is omitted herein for the sake of brevity.

The deposition device 100 may also include a mechanism 280 for moving the substrate 120. The mechanism 280 may include a motor or an actuator that pulls or pushes the substrate 120 to the right direction as illustrated in FIG. 2. As the substrate 120 is move progressively to the right, substantially entire surface of the substrate 120 is exposed to the source precursor and the reactant precursor, depositing material on the substrate 120 as a result.

By having an opposing set of reactors, the source precursor and the reactant precursor flow perpendicular to the surface of the substrate 120 as well as in parallel to the surface of the substrate 120. Therefore, a layer of conformal material is deposited on the flat surface as well as the pores or holes in the substrate 120. Hence, the material is deposited more evenly and completely on the substrate 120.

In order to reduce the precursor material leaked outside the deposition device, the distance H between the substrate 120 and the upper/lower reactor 130A, 130B is maintained at a low value. In one embodiment, the distance H is less than 1 mm, and more preferably less than tens of μms.

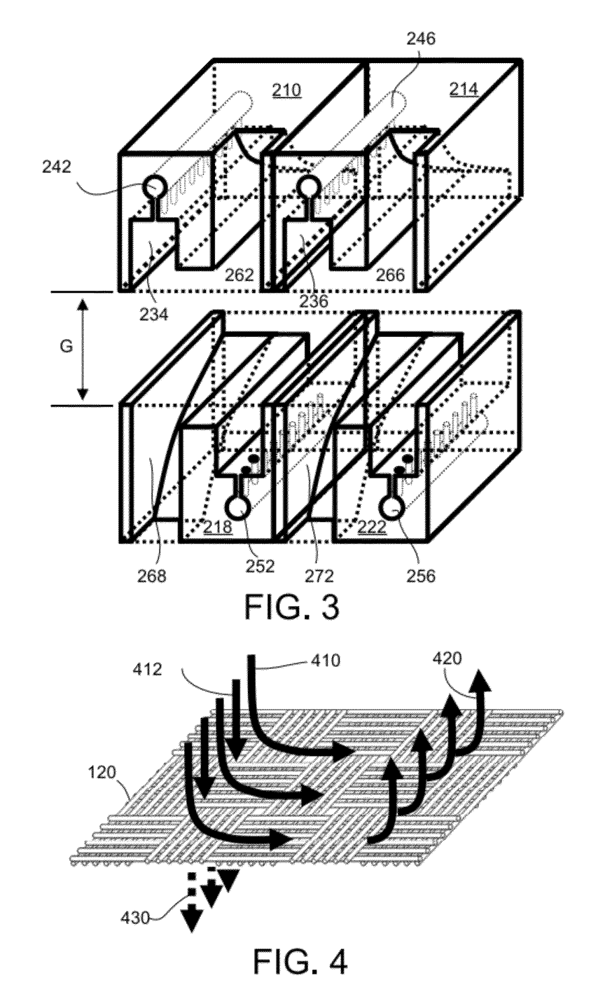

FIG. 3 is a perspective view of the deposition device 100 of FIG. 1 cut in half, according to one embodiment. As shown in FIG. 3, the exhaust portions 262, 266, 268, 272 have a curved interior surface to receive the excess source precursor and the excess reactant precursor across substantially the entire length of the deposition device 100. The upper reactor 130A and the lower reactor 130B are separated by distance G. The distance G is sufficient to enable the substrate 120 to pass between but not excessively large to allow precursor to leak out between the clearance between the substrate 120 and the reactors 130A, 130B.

FIG. 4 is a diagram illustrating flow of source precursor below a source injector 202, according to one embodiment. The source precursor is injected downward by the perforations 244 as shown by arrows 410, 412. Some of the source precursor moves in parallel to the upper surface of the substrate 120 as shown by arrow 410 and is then discharged via the exhaust portion 262 as indicated by arrow 420. The remaining source precursor flows down as shown by arrow 412, penetrates the substrate 120 and flows downwards through the exhaust portion 268 of the source injector 206. As shown in FIG. 4, the injected source precursor partially penetrates the substrate while the remaining source precursor flows along the substrate 120. In this way, the entire substrate 120 is absorbed with the source injector. Although not illustrated, the precursor injector also flows through the substrate 120 or flows along the surface of the substrate 120.

In one embodiment, trimethylaluminum (TMA) is used as the source precursor and O₃ is used as the reactant precursor to deposit Al₂O₃ on the substrate 120. In another embodiment, TMA is used as the source precursor and NH₃ is used as the reactant precursor to deposit AN on the substrate 120. Various other combinations of source precursor and reactant precursor may be used to deposit different materials on the substrate 120.

In one embodiment, purge injectors for injecting purge gas (e.g., Argon gas) are provided between the source injectors and the reactant injectors. These purge injectors remove excess source precursor from the substrate and promote growth of a conformal layer on the surface of the substrate and pores of the substrate. Purge injectors may also be provided next to the reactant injectors to remove excess reactant precursor from the substrate.

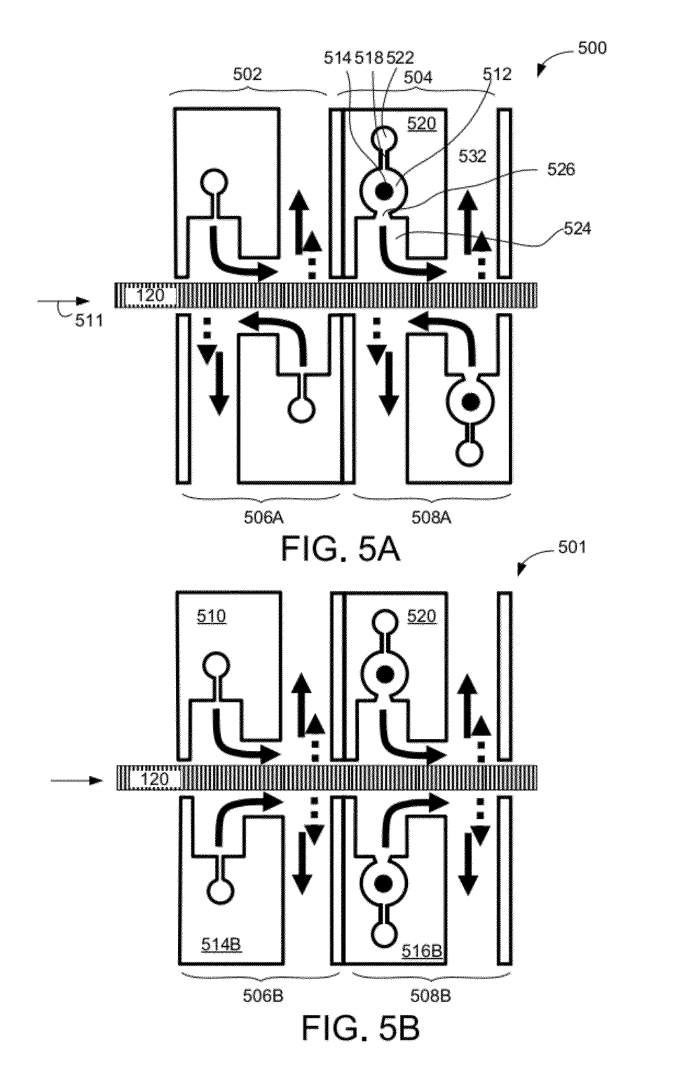

In one embodiment, radical reactors may be provided in the upper and lower reactors to inject radicals of gas as reactant precursor onto the substrate. FIG. 5A is a cross sectional view of a deposition device 500 including radical reactors 504, 508A, according to one embodiment. The deposition device 500 is substantially the same as the deposition device 100 except that the injectors 204, 208 are replaced with the radical reactors 504, 508A.

The deposition device 500 includes source injectors 502, 506A and the radical reactors 504, 508A. The structure and function of the source injectors 502, 506A are the same as the source injectors 202, 206, and therefore, the description thereof is omitted for the sake of brevity. The permeable substrate 120 moves from the left to the right as shown by arrow 511 in FIG. 5A so that the permeable substrate 120 is exposed first to the source precursor (by the source injectors 502, 506A) and then the radicals (by the radical reactors 504, 508A).

The radical reactor 504 may include, among other components, an inner electrode 514 and a body 520. The body 520 may be formed with, among other structures, a channel 522, perforations (e.g., holes or slits) 518, a plasma chamber 512, an injection holes 526, a reaction chamber 524 and an exhaust portion 532. Gas is provided into the plasma chamber 512 via the channel 522 and the perforations 518. Voltage difference is applied between the inner electrode 514 and the body 520 of the radical reactor 504 to generate plasma within the plasma chamber 512. The body 520 of the radical reactor 504 functions as an outer electrode. In an alternative embodiment, an outer electrode separate from the body 520 may be provided to surround the plasma chamber 512. As a result of generating the plasma, radicals of the gas is formed in the plasma chamber 512 and injected into the reaction chamber 524 via the injection holes 526.

As described above with reference to FIG. 4, part of the radicals generated by the radical reactors 504, 508A penetrate the substrate and are discharged by exhaust portions provided in the radical reactors of the opposite side. The other radicals flow in parallel to the surface of the substrate 120 and are discharged by the exhaust portions of the radical reactor that generated the radicals.

FIG. 5B is a cross sectional view of a deposition device 501 including radical reactors 520, 508B, according to another embodiment. The deposition device 501 is substantially the same as the deposition device 500 except that the orientation of the source injector 506B and the radical reactor 508B is opposite to the counterpart components of the deposition device 500.

In one embodiment, the source precursor injected by the source injectors 502, 506A or 506B is trimethylaluminum (TMA) and the reactant precursor injected by the radical reactors 504, 508A or 508B are O* radicals. The deposited material is Al₂O₃, which affords water resistance to the permeable substrate.

In another embodiment, the source precursor injected by the source injectors 502, 506A or 506B is trimethylaluminum (TMA) and the reactant precursor injected by the radical reactors 504, 508A or 508B is O* radicals. The deposited material is AlN or AlON.

In another embodiments, dielectric material (e.g., SiN) or metal (e.g., TiN) layer are deposited on the substrate using combinations of source precursor and reactant precursor well known in the art. SiN or TiN layer advantageously affords water resistant or water repellent properties to the substrate.

In still another embodiment, Ag or AgO is deposited on the permeable substrate using combinations of source precursor and reactant precursor well known in the art. Ag or AgO layer affords anti-microbial properties to the substrate.

In yet another embodiment, graphene, amorphous carbon, diamond like carbon (DLC) or their combinations may be deposited on the substrate to increase the strength of the substrate as well as affording different functionality to the substrate.

In other embodiments, hybrid organic-inorganic layer (e.g., alucon having (Al—O—R—O)ₙ-structure)) may be deposited on hydrophilic substrate to afford water repellent properties. Conductive materials such as Al, Cu, TiN or Indium tin oxide (ITO) may also be deposited on the permeable substrate to fabricate conductive sheet or for reducing damages due to electrostatic shocks on electronic devices.

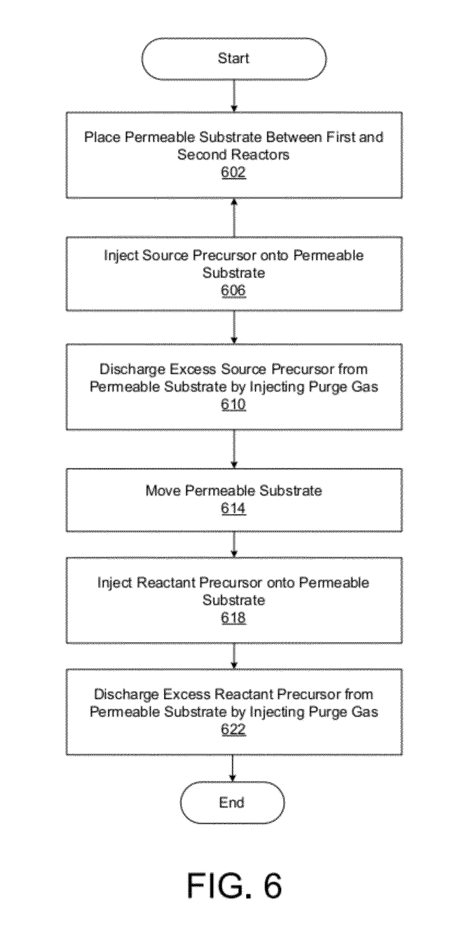

FIG. 6 is a flowchart for a process of depositing material on a permeable substrate, according to one embodiment. The permeable substrate is placed 602 between a first reactor (e.g., the upper reactor 130A) and a second reactor (e.g., the lower reactor 130B). The first reactor, the second reactor or both of the reactors inject 606 source precursor onto the substrate 120. Excess source precursor remaining after being absorbed by the substrate 120 is discharged 610 by the first reactor and the second reactor. The first reactor, the second reactor or both of the reactors may also inject purge gas to discharge excess source precursor from the substrate 120.

The substrate 120 is then moved 614 to place a portion of the substrate 120 previously injected with the source precursor to a location for injecting reactant precursor by the first reactor, the second reactor or both. The first reactor, the second reactor or both of the reactors inject 618 reactant precursor onto the substrate 120 to deposit a layer of material on the surface of the substrate 120 and in the pores of the substrate 120.

The first reactor, the second reactor or both of the reactors may also inject purge gas to discharge 622 excess reactant precursor from the permeable substrate.

The processes 602 through 622 may be repeated for a predetermined number of times to deposit a layer of materials of a predetermined thickness.

In above embodiments, the upper and lower reactors deposit the same material on the substrate. However, in other embodiments, each of the upper and lower reactors may inject different gases to deposit a different material on both sides of the substrate.

In one or more embodiment, the substrate deposited with the material may be subject to additional processes such as exposure to ultraviolet (UV) ray, microwave or magnetic field after, during or before being exposed to precursor molecules.

Depositing materials on permeable substrate using the embodiments is advantageous, among other reasons, because (i) the process can be performed at a low temperature (e.g., below 150° C.), (ii) the deposited material has strong adhesion to the substrate, and (iii) various processes (e.g., radical surface treatment) can be performed on the substrate in-situ without moving the substrate to a different device.

The substrate deposited with material using embodiments described herein may have higher melting point or retain its shape at a high temperature. The embodiments also results in a substrate with a conformal layer, enabling the substrate to be used as separators in rechargeable battery with higher packing density. Further, embodiments enable use of less precursor materials to deposit materials on the substrate, resulting in lower production cost.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. A deposition device for depositing material on a permeable substrate, comprising:
a first reactor facing one surface of the permeable substrate and configured to inject a first precursor onto the surface of the permeable substrate;
a second reactor facing another surface of the permeable substrate and configured to inject a second precursor onto the other surface of the permeable substrate, at least part of the first precursor penetrating the permeable substrate and discharged by the second reactor; and
a mechanism for causing relative movement between the permeable substrate and the first and second reactors.

2. The deposition device of claim 1, wherein the first reactor comprises a first injector configured to inject the first precursor onto the surface, and the second reactor comprises a second injector configured to inject the second precursor onto the other surface of the permeable substrate, each of the first and second injectors comprising a body formed with a reaction chamber facing the permeable substrate.

3. The deposition device of claim 2, wherein the body is further formed with an exhaust portion, and a constriction zone connecting the exhaust portion and the reaction chamber, the exhaust portion configured to discharge excess portion of the first precursor or excess portion of the second precursor.

4. The deposition device of claim 3, wherein the constriction zone has a height less than ⅔ of the reaction chamber.

5. The deposition device of claim 2, wherein the first reactor further comprises a third injector configured to inject a third precursor onto the surface of the permeable substrate, and the second reactor further comprises a fourth injector configured to inject a fourth precursor onto the other surface of the permeable substrate.

6. The deposition device of claim 5, wherein the first precursor and the second precursor are source precursor for performing atomic layer deposition (ALD) or molecular layer deposition (MLD) and the third precursor and the fourth precursor are reactor precursor for performing the ALD or the MLD.

7. The deposition device of claim 1, wherein the first precursor and the second precursor are a same material.

8. The deposition device of claim 2, wherein the first reactor comprises a first radical reactor configured to inject first radicals onto the surface, and the second reactor comprises a second radical reactor configured to inject second radicals onto the other surface.

9. The deposition device of claim 8, wherein each of the first and second the radical reactors comprises a body formed with a radical chamber and an electrode extending within the radical chamber, wherein voltage difference is applied between the body and the electrode to generate plasma within the radical chamber.

10. The deposition device of claim 9, wherein the body is formed with one or more injection holes connected to the radical chamber to inject the radicals onto the substrate.

11. A method of depositing material on a permeable substrate, comprising:
injecting a first precursor onto a surface of the permeable substrate by a first reactor facing the surface of the permeable substrate;
injecting a second precursor onto another surface of the permeable substrate by a second reactor facing the other surface of the permeable substrate;
discharging at least part of the first precursor that penetrated the permeable substrate by the second reactor; and
causing relative movement between the permeable substrate and the first and second reactors.

12. The method of claim 11, further comprising:
discharging excess portion of the first precursor remaining after injection onto the substrate by the first reactor; and
discharging excess portion of the second precursor remaining after injection onto the substrate by the second reactor.

13. The method of claim 11, further comprising at least part of the second precursor that penetrated the permeable substrate by the first reactor.

14. The method of claim 11, further comprising:
injecting a third precursor on the surface of the permeable substrate by the first reactor; and
injecting a fourth precursor on the other substrate of the permeable substrate by the second reactor.

15. The method of claim 14, wherein the first precursor and the second precursor are source precursor for performing atomic layer deposition (ALD) or molecular layer deposition (MLD), and the third precursor and the fourth precursor are reactor precursor for performing the ALD or the MLD.

16. The method of claim 14, wherein the first precursor and the second precursor comprise trimethylaluminum (TMA) and the third and the fourth precursor comprise ozone.

17. The method of claim 11, wherein the first precursor and the second precursor are a same material.

18. The method of claim 11, further comprising:
injecting first radicals on the surface of the permeable substrate by the first reactor; and
injecting second radicals on the other substrate of the permeable substrate by the second reactor.

19. The method of claim 18, further comprising:
applying voltage difference between a body of the first reactor and an electrode extending across a radical chamber formed in the first reactor to generate the first radicals; and
applying voltage difference between a body of the second reactor and an electrode extending across a radical chamber formed in the second reactor to generate the second radicals.

20. The method of claim 11, further comprising injecting purge gas to remove excess portion of the first precursor or excess portion of the second precursor from the permeable substrate.
